(19) United States
(12) Patent Application Publication
(10) Pub. No.: US 2024/0011715 A1
(43) Pub. Date: Jan. 11, 2024

(54) HEAT PIPE

(71) Applicant: FURUKAWA ELECTRIC CO., LTD., Tokyo (JP)

(72) Inventor: Masahiro UEKUBO, Tokyo (JP)

(73) Assignee: FURUKAWA ELECTRIC CO., LTD., Tokyo (JP)

(21) Appl. No.: 18/251,997

(22) PCT Filed: Nov. 12, 2021
(86) PCT No.: PCT/JP2021/041763

§ 371 Date: May 5, 2023

(30) Foreign Application Priority Data
Nov. 13, 2020 (JP) 2020-189754

(51) Int. Cl. F28D 15/04

(52) U.S. Cl. CPC F28D 15/04

(57) ABSTRACT

A heat pipe includes a container having an internal space for a working fluid, and an evaporating portion that evaporates a liquid-phase working fluid to change it into a gas-phase working fluid. A condensing portion separated from the evaporating portion condenses a gas-phase working fluid to change it into a liquid-phase working fluid, and an intermediate portion located between the evaporating portion condensing portion. The heat pipe includes a first sintered body layer on an inner peripheral surface of the evaporating portion and includes a product of sintering a first copper powder. A second sintered body layer continuously extends to at least a part of an inner peripheral surface of the intermediate portion and stacked on an inner peripheral surface of the first sintered body layer and includes a product of sintering of a second copper powder having a larger average particle size than the first copper powder.

### TECHNICAL FIELD

The present invention relates to a heat pipe having heat transfer characteristics.

### BACKGROUND ART

In recent years, electronic components such as semiconductor elements mounted on electric and electronic devices such as digital cameras and mobile phones, including notebook computers, tend to generate more heating value due to high-density mounting associated with higher functionality, and thus it is important to adopt a configuration that enables the electronic components to be efficiently cooled. An example of means for cooling the electronic components may include a method of cooling using a heat pipe.

Here, the heat pipe generally includes a tubular vessel (container) including an internal space in which a working fluid is sealed. The tubular vessel includes: an evaporating portion that is provided on one end side and evaporates a liquid-phase working fluid to change a phase into a gas-phase working fluid; and a condensing portion that is provided on the other end side and condenses the gas-phase working fluid to change a phase into a liquid-phase working fluid. The working fluid, which has undergone the phase change from the liquid phase into the gas phase in the evaporating portion, flows from the evaporating portion to the condensing portion. The working fluid, which has undergone the phase change from the gas phase into the liquid phase in the condensing portion, flows from the condensing portion to the evaporating portion. In this way, a circulation flow of the working fluid is formed between the evaporating portion and the condensing portion in the tubular vessel, and thus heat is transferred between the evaporating portion and the condensing portion in the tubular vessel.

An example of a conventional heat pipe may include a configuration in which a wick structure (hereinafter, sometimes referred to as a “wick structure (metal powder)”) made of a sintered body of particulate metal powder is provided in an evaporating portion of a container. The wick structure (metal powder) constituting the evaporating portion is excellent in holding power of a liquid-phase working fluid. At this time, when the heat pipe is installed in a so-called top heat posture, that is, a posture in which the evaporating portion is installed above the condensing portion, dry-out (a phenomenon in which the working fluid is depleted) can be prevented.

In addition, the inventors have proposed a heat pipe in Patent Document 1 in which the other wick structure (hereinafter, sometimes referred to as a “wick structure (metal fiber)”) made of a sintered body of metal fiber is formed in an intermediate portion located between an evaporating portion and a condensing portion to be connected to a wick structure (metal powder) of the evaporating portion, thereby further increasing a capillary force in the intermediate portion, promoting a reflux of a liquid-phase working fluid from the condensing portion toward the evaporating portion, and improving heat transfer characteristics.

Patent Document 1: PCT International Publication No. WO2019/131790

### DISCLOSURE OF THE INVENTION

### Problems to be Solved by the Invention

In the heat pipe disclosed in Patent Document 1, when the liquid-phase working fluid flows from the wick structure (metal fiber) in the intermediate portion toward the wick structure (metal powder) in the evaporating portion, the liquid-phase working fluid may be retained in the vicinity of a boundary between the intermediate portion and the evaporating portion, and thus droplets may be formed. The droplets formed in the vicinity of the boundary between the evaporating portion and the condensing portion collide with a part of the gas-phase working fluid flowing from the evaporating portion toward the condensing portion, a so-called counterflow is generated in the gas-phase working fluid, and thus turbulence in a circulation flow of the working fluid may be generated. When the turbulence in the circulation flow of the working fluid is generated, thermal resistance tends to increase. Therefore, it is desirable to develop a novel configuration that prevents the turbulence in the circulation flow of the working fluid in order to further improve heat transfer characteristics of the heat pipe.

Accordingly, the heat pipe of Patent Document 1 has room for improvement in terms of reducing the thermal resistance and improving the heat transfer characteristics.

An object of the present invention is to provide a heat pipe having low thermal resistance and excellent heat transfer characteristics.

### Means for Solving the Problems

In order to achieve the above object, the present invention has main configurations as follows.
(1) A heat pipe including a container having an internal space in which a working fluid is sealed, the container including: an evaporating portion that evaporates a liquid-phase working fluid to change it into a gas-phase working fluid; a condensing portion that is disposed at a position separated from the evaporating portion and condenses the gas-phase working fluid to change it into a liquid-phase working fluid; and an intermediate portion located between the evaporating portion and the condensing portion, the heat pipe including: a first sintered body layer that is located on an inner peripheral surface of the evaporating portion of the container and includes a product of sintering of a first copper powder; and a second sintered body layer that is located to continuously extend to at least a part of an inner peripheral surface of the intermediate portion and stacked on an inner peripheral surface of the first sintered body layer and includes a product of sintering of a second copper powder having a larger average particle size than the first copper powder.
(2) In the heat pipe according to (1) described above, a plurality of grooves extending in a longitudinal direction of the container are formed on an inner peripheral surface of the container, and the second sintered body layer substantially isolates, at a position of the intermediate portion, a vapor flow of the gas-phase working fluid, which has undergone a phase change by the evaporating portion, from a liquid flow of the liquid-phase working fluid, which has undergone a phase change by the condensing portion, and the liquid flow has a path passing through the plurality of grooves and a path passing through an internal cavity of the second sintered body layer.
(3) In the heat pipe according to (2) described above, the first sintered body layer is filled in at least one part of the grooves.
(4) In the heat pipe according to any one of (1) to (3) described above, the inner peripheral surface of the first sintered body layer is provided closer to a central position of the internal space of the container than a boundary surface position located in the intermediate portion where the second sintered body layer and the inner peripheral surface of the container are in contact with each other.
(5) In the heat pipe according to any one of (1) to (4) described above, the second sintered body layer is located to extend continuously to the inner peripheral surface of the intermediate portion.
(6) In the heat pipe according to any one of (1) to (5) described above, the first sintered body layer is provided so as to include a side of the container with respect to a virtual inner peripheral surface obtained by imagining a case where the grooves are not formed in the evaporating portion of the container.
(7) In the heat pipe according to any one of (1) to (6) described above, the second sintered body layer extends so as to be in contact with both the inner peripheral surface of the first sintered body layer and the inner peripheral surface of the intermediate portion.
(8) In the heat pipe according to (1) described above, a liquid flow of the liquid-phase working fluid is divided into a path passing through a plurality of grooves extending in the longitudinal direction of the container and a path passing through an internal cavity of the second sintered body layer.

### Effects of the Invention

According to the present invention, it is possible to provide a heat pipe having low thermal resistance and excellent heat transfer characteristics.

### BRIEF DESCRIPTION OF THE DRAWINGS

FIGS. 1A to 1C are views showing an internal structure of a heat pipe of a first embodiment, FIG. 1A is a vertical cross-sectional view, FIG. 1B is a cross-sectional view taken along a line I_{A}-I_{A} in FIG. 1A, and FIG. 1C is a cross-sectional view taken along a line I_{B}-I_{B} in FIG. 1A;

FIG. 2 is a vertical cross-sectional view illustrating a flow of a working fluid generated inside the heat pipe of FIGS. 1A to 1C during operation;

FIGS. 3A to 3C are views showing an internal structure of a heat pipe of a second embodiment, FIG. 3A is a vertical cross-sectional view, FIG. 3B is a cross-sectional view taken along a line II_{A}-II_{A} in FIG. 3A, and FIG. 3C is a cross-sectional view taken along a line II_{R}-II_{R} in FIG. 3A;

FIGS. 4A to 4C are views showing an internal structure of a heat pipe of a third embodiment, FIG. 4A is a vertical cross-sectional view, FIG. 4B is a cross-sectional view taken along a line III_{A}-III_{A} in FIG. 4A, and FIG. 4C is a cross-sectional view taken along a line III_{B}-III_{B} in FIG. 4A;

FIGS. 5A to 5C are views showing an internal structure of a heat pipe of a fourth embodiment, FIG. 5A is a vertical cross-sectional view, FIG. 5B is a cross-sectional view taken along a line IV_{A}-IV_{A} in FIG. 5A, and FIG. 5C is a cross-sectional view taken along a line IV_{B}-IV_{B} in FIG. 5A;

FIGS. 6A to 6C are views showing an internal structure of a heat pipe of a fifth embodiment, FIG. 6A is a vertical cross-sectional view, FIG. 6B is a cross-sectional view taken along a line V_{A}-V_{A} in FIG. 6A, and FIG. 6C is a cross-sectional view taken along a line V_{B}-V_{B} in FIG. 6A;

FIGS. 7A to 7C are views showing an internal structure of a heat pipe of a sixth embodiment, FIG. 7A is a vertical cross-sectional view, FIG. 7B is a cross-sectional view taken along a line VI_{A}-VI_{A} in FIG. 7A, and FIG. 7C is a cross-sectional view taken along a line VI_{B}-VI_{B} in FIG. 7A;

FIGS. 8A to 8C are views showing an internal structure of a heat pipe of a seventh embodiment, FIG. 8A is a vertical cross-sectional view, FIG. 8B is a cross-sectional view taken along a line VII_{A}-VII_{A} in FIG. 8A, and FIG. 8C is a cross-sectional view taken along a line VII_{B}-VII_{B} in FIG. 8A;

FIGS. 9A to 9C are views showing an internal structure of a heat pipe of an eighth embodiment, FIG. 9A is a vertical cross-sectional view, FIG. 9B is a cross-sectional view taken along a line VIII_{A}-VIII_{A} in FIG. 9A, and FIG. 9C is a cross-sectional view taken along a line VIII_{B}-VIII_{B} in FIG. 9A;

FIG. 10 is a vertical cross-sectional view showing an internal structure of a heat pipe of a ninth embodiment; and

FIGS. 11A to 11D are vertical cross-sectional views showing internal structures of heat pipes of Invention Example and Comparative Examples, wherein FIG. 11A is a partial cross-sectional view of a heat pipe of Invention Example, FIG. 11B is a partial cross-sectional view of a heat pipe of Comparative Example 1, FIG. 11C is a partial cross-sectional view of a heat pipe of Comparative Example 2, and FIG. 11D is a partial cross-sectional view of a heat pipe of Comparative Example 3.

### PREFERRED MODE FOR CARRYING OUT THE INVENTION

Heat pipes according to some embodiments of the present invention will be described below.

### First Embodiment

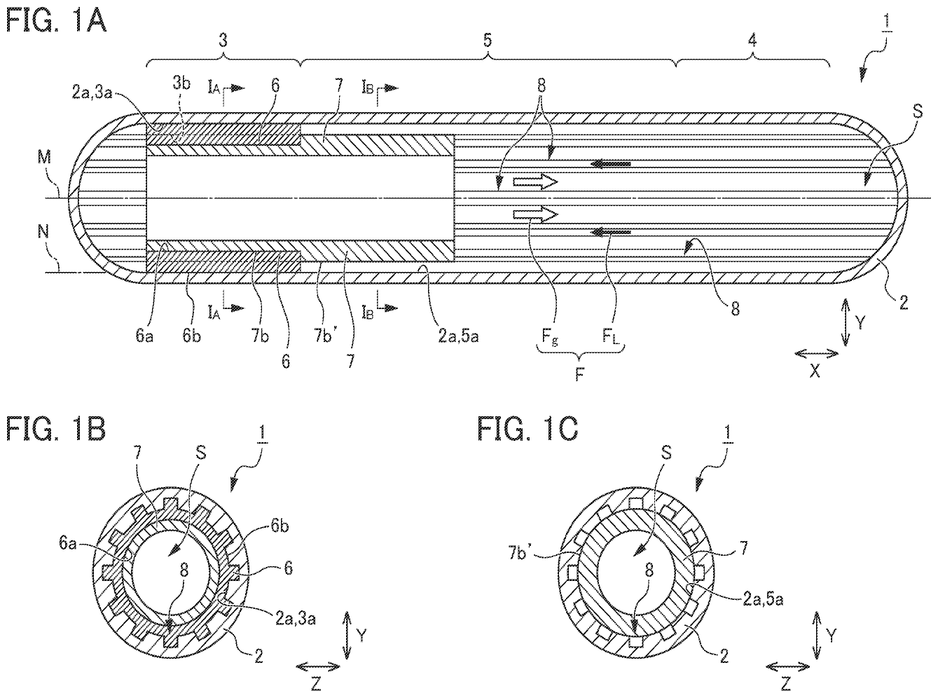

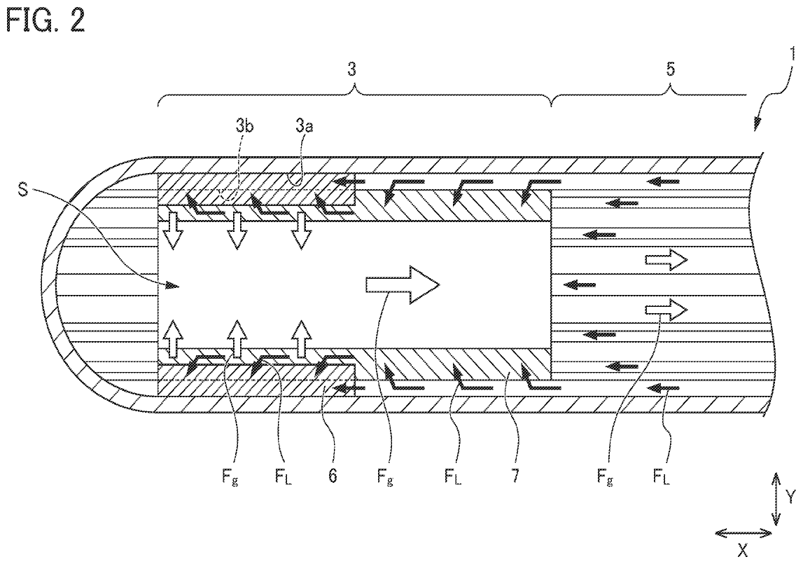

FIGS. 1A to 1C are views showing an internal structure of a heat pipe of a first embodiment, wherein FIG. 1A is a vertical cross-sectional view, FIG. 1B is a cross-sectional view taken along a line I_{A}-I_{A} in FIG. 1A, and FIG. 1C is a cross-sectional view taken along a line I_{D}-I_{D} in FIG. 1A. On the other hand, FIG. 2 is a vertical cross-sectional view illustrating a flow of a working fluid generated inside the heat pipe of FIGS. 1A to 1C during operation.

A heat pipe 1 includes a container 2 such as a tubular vessel having an internal space S in which a working fluid F is sealed, the container 2 including an evaporating portion 3 that evaporates a liquid-phase working fluid F_{T}. to change a phase into a gas-phase working fluid F_{g}, a condensing portion 4 that is disposed at a position separated from the evaporating portion 3 and condenses the gas-phase working fluid F_{g} to change a phase into a liquid-phase working fluid F_{L}, and an intermediate portion 5 located between the evaporating portion 3 and the condensing portion 4. Here, the heat pipe 1 includes a first sintered body layer 6 that is located on an inner peripheral surface 3a of the evaporating portion 3 of the container 2 and is formed by sintering a first copper powder and a second sintered body layer 7 that continuously extends to at least a part of an inner peripheral surface 5a of the intermediate portion 5 while being laminated on an inner peripheral surface 6a of the first sintered body layer 6 and is formed by sintering a second copper powder having a larger average particle size than the first copper powder.

In the heat pipe 1, since the liquid-phase working fluid F_{L} flows from the inner peripheral surface 5a of the intermediate portion 5 toward a leading end of the evaporating portion 3 in a longitudinal direction X of the container through a cavity formed inside the second sintered body layer 7 when the second sintered body layer 7 formed of the second copper powder having a larger average particle size than the first copper powder is laminated on the inner peripheral surface 6a of the first sintered body layer 6 formed of the first copper powder, contact of the liquid-phase working fluid F_{T}. passing through the inside of the second sintered body layer 7 with the gas-phase working fluid (g) passing through the internal space S can be reduced. Particularly, in the heat pipe 1, since the second sintered body layer 7 laminated on the inner peripheral surface 6a of the first sintered body layer 6 in the evaporating portion 3 extends to the inner peripheral surface 5a of the intermediate portion 5 and thus the liquid-phase working fluid F_{L} sucked up to the second sintered body layer 7 is smoothly supplied to the inner peripheral surface 6a of the first sintered body layer 6, retention of the liquid-phase working fluid F_{T}. can hardly occur at a boundary location between the intermediate portion 5 and the evaporating portion 3. As a result, a counterflow of the gas-phase working fluid (g) hardly occurs in the heat pipe 1, so that turbulence in a circulation flow of the working fluid F can be prevented.

In the heat pipe 1, the liquid-phase working fluid F_{L} flows from the inner peripheral surface 5a of the intermediate portion 5 toward the leading end of the evaporating portion 3 in the longitudinal direction X of the container, so that the liquid-phase working fluid F_{L} can be supplied to a wider range of the inner peripheral surface 6a of the first sintered body layer 6 in the evaporating portion 3. As a result, in the heat pipe 1, when the liquid-phase working fluid F_{L} is evaporated in the evaporating portion 3, heat is transferred to the liquid-phase working fluid F_{L} reaching the inner peripheral surface of the first sintered body layer 6 and the cavity formed therein, and thus the liquid-phase working fluid F_{L} can be efficiently evaporated.

As described above, since the heat pipe 1 can prevent turbulence in the circulation flow of the working fluid F and can efficiently evaporate the liquid-phase working fluid F_{L}, it is possible to provide a heat pipe having excellent heat transfer characteristics and small thermal resistance.

### [Configuration of Container]

The heat pipe 1 shown in FIGS. 1 and 2 includes the container 2 having the internal space S in which the working fluid F is sealed. In FIGS. 1 and 2, the tubular vessel is described as an example of the container 2.

Here, the extending shape of the container 2 in the longitudinal direction X is not particularly limited, and may include a shape having a curved portion in addition to a linear shape shown in FIG. 1A. Further, an outer surface contour shape of the container 2 is not particularly limited when being cut in a direction orthogonal to the longitudinal direction X of the container 2, and may include, for example, a flat shape and a polygonal shape such as a quadrangle in addition to a substantially circular shape shown in FIGS. 1B and 1C. A thickness of the container 2 is not particularly limited, and may be, for example, in a range of 0.05 mm to 1.0 mm. An outer diameter of the container 2 is not particularly limited, but is preferably in a range of 5 mm to 20 mm, for example, when the container 2 has the outer surface contour shape of the substantially circular shape shown in FIGS. 1B and 1C.

A material of the container 2 is not particularly limited. In particular, when an aqueous liquid is used as the working fluid F, a metal material is preferably used from the viewpoint of improving wettability with the working fluid F. In particular, for example, copper and copper alloys can be used for the container 2 from the viewpoint of excellent thermal conductivity. In addition, from the viewpoint of weight reduction, for example, aluminum and aluminum alloys can be used for the container 2. Further, from the viewpoint of high strength, for example, stainless steel can be used for the container 2. In addition, for example, tin, tin alloys, titanium, titanium alloys, nickel, and nickel alloys can be used for the container 2 depending on the usage situation.

### [Configuration of Evaporating Portion, Condensing Portion, and Intermediate Portion]

The container 2 includes the evaporating portion 3 that evaporates the liquid-phase working fluid F_{L} to change the phase into the gas-phase working fluid F₉, the condensing portion 4 that is disposed at the position separated from the evaporating portion 3 and condenses the gas-phase working fluid F_{q} to change the phase into the liquid-phase working fluid F_{L}, and the intermediate portion 5 located between the evaporating portion 3 and the condensing portion 4. Here, each of the evaporating portion 3, the condensing portion 4, and the intermediate portion 5 can be provided in a part of the container 2 in the longitudinal direction X. The container 2 shown in FIGS. 1A to 1C is configured as a sealed tube in which the evaporating portion 3 is provided on one end side thereof, the condensing portion 4 is provided on the other end side, and the intermediate portion 5 is provided between the evaporating portion 3 and the condensing portion 4.

The evaporating portion 3 is formed on one end side of the container 2 in FIGS. 1A to 1C, and has a function of receiving heat (absorbing heat) from a heating element (not shown) which is thermally connected. Specifically, as shown in FIG. 2, the evaporating portion 3 evaporates the liquid-phase working fluid F_{L} to change the phase into the gas-phase working fluid F_{g}, thereby absorbing heat as evaporation latent heat received from the heating element (not shown).

In the evaporating portion 3, the heat generated from the heating element is transferred to the first sintered body layer 6 through the container 2, and the heat is further transferred from the first sintered body layer 6 to the second sintered body layer 7. On the other hand, as shown in FIG. 2, the liquid-phase working fluid F_{L} supplied to the evaporating portion 3 is supplied from the second sintered body layer 7 to the first sintered body layer 6 in the evaporating portion 3. Therefore, the phase change of the liquid-phase working fluid F_{L} into the gas-phase working fluid F_{g} in the evaporating portion 3 is mainly performed in the first sintered body layer 6, but may be partially performed in the second sintered body layer 7. At this time, the gas-phase working fluid F_{g} generated by evaporation of the liquid-phase working fluid F_{L} in the first sintered body layer 6 moves to the internal space S through the cavity formed inside the second sintered body layer 7.

In addition, the condensing portion 4 is disposed at the position separated from the evaporating portion 3, for example, is disposed on the other end side of the container 2 in FIGS. 1A to 1C. The condensing portion 4 has a function of dissipating the evaporation latent heat of the gas-phase working fluid F_{g}, which has undergone the phase change and been transferred by the evaporating portion 3, by using heat exchange means (not shown). In the condensing portion 4, the gas-phase working fluid F_{g} is condensed to change the phase into the liquid-phase working fluid F_{L}, whereby the heat transferred as condensation latent heat of the working fluid F is released to the outside of the heat pipe 1.

### [Configuration of Groove]

In the heat pipe 1, a plurality of grooves 8 extending in the longitudinal direction X of the container 2 are preferably formed on the inner peripheral surface 2a of the container 2. In FIGS. 1A to 1C, for example, the plurality of grooves 8 are formed on a wall side of the container 2 from the inner peripheral surface 2a of the container 2. By these grooves 8, when the liquid-phase working fluid F_{T}. is transferred inside the heat pipe 1, a capillary force can be exerted such that the liquid-phase working fluid F_{L} moves onto the inner peripheral surface 2a of the container 2 along the grooves 8. For this reason, it is possible to promote the transfer of the liquid-phase working fluid F_{T}. from the condensing portion 4 to the evaporating portion 3.

These grooves 8 preferably extend at least on the inner peripheral surface 2a in the longitudinal direction X from the condensing portion 4 toward a portion where the second sintered body layer 7 to be described below is located, and the grooves 8 more preferably extend continuously from the condensing portion 4 to the evaporating portion 3. Thereby, since the transfer of the liquid-phase working fluid F_{L} is promoted from the condensing portion 4 to the portion where the second sintered body layer 7 is located, it is possible to promote the transfer of the liquid-phase working fluid F_{L} to the first sintered body layer 6 in the evaporating portion 3 through the second sintered body layer 7. In particular, when the grooves 8 extending continuously from the condensing portion 4 to the evaporating portion 3 are provided, it is possible to supply the liquid-phase working fluid F_{T}. to the first sintered body layer 6, which is located in the evaporating portion 3, through both a path passing through the inside of the second sintered body layer 7 and a path passing through the grooves 8.

The container 2 including the grooves 8 may be a groove tube in which the grooves 8 extending in the longitudinal direction X of the container 2 are formed on the inner peripheral surface 2a of the container 2. In particular, when the container 2 is configured with the groove tube, since the capillary force is exerted over the entire length of the container 2 to transfer the liquid-phase working fluid F_{L}, the liquid-phase working fluid F_{L} can be easily transferred from the condensing portion 4 toward the evaporating portion 3 when the heat pipe 1 is installed in a top heat posture, that is, even when the evaporating portion 3 located in the downstream of the liquid-phase working fluid F_{L} is installed above the condensing portion 4 and the intermediate portion 5.

An opening width of these grooves 8 is not particularly limited, but may be, for example, 0.1 mm to 1 mm from the viewpoint of promoting the transfer of the liquid-phase working fluid F_{L} by the capillary force.

### [Configuration of First Sintered Body Layer]

The first sintered body layer 6 is a sintered body layer that is located on the inner peripheral surface 3a of the evaporating portion 3 in the container 2 and is formed by sintering the first copper powder. Since the first sintered body layer 6 is formed of a sintered body of the first copper powder having a smaller average particle size than the second sintered body layer 7 to be described below, the cavity through which the liquid-phase working fluid F_{L} can flow is small, and a flow rate of the liquid-phase working fluid F_{L} is slow. Further, since the first sintered body layer 6 is adjacent to the inner peripheral surface 3a of the evaporating portion 3 in the container 2, it is also a portion where a temperature tends to be relatively high. Therefore, as shown in FIG. 2, the flow of the working fluid F inside the first sintered body layer 6 mainly includes a flow of the liquid-phase working fluid F_{L} that is supplied from the inner peripheral surface 6a and is infiltrated into the inside of the first sintered body layer 6 and a flow of the gas-phase working fluid F_{y} that is generated by evaporation of the liquid-phase working fluid F_{L} infiltrated into the inside of the first sintered body layer 6 and is directed toward the internal space S from the inside of the first sintered body layer 6 through the inner peripheral surface 6a. In addition, a space of the grooves 8 can be configured to exist between the inner peripheral surface 2a of the container and an outer peripheral surface 6b of the first sintered body layer 6, whereby the liquid-phase working fluid F_{L}, which has undergone the phase change by the condensing portion 4, can be moved more quickly through the groove 8 to the position of the evaporating portion 3 where the outer peripheral surface of the first sintered body layer 6 exists, and as a result, it is possible to further promote the circulation flow of the liquid-phase working fluid F_{L} from the condensing portion 4 to the evaporating portion 3.

As shown in FIG. 1A, the first sintered body layer 6 is provided at least in the evaporating portion 3. Since the evaporation of the liquid-phase working fluid F_{L} in the evaporating portion 3 is promoted by the first sintered body layer 6 provided in the evaporating portion 3, the heat received from the heating element (not shown) thermally connected to the evaporating portion 3 can be absorbed by more working fluid F as the evaporation latent heat. The first sintered body layer 6 may be configured such that a part thereof extends to the intermediate portion 5.

Further, the first sintered body layer 6 is formed of the sintered body of the first copper powder, and is configured with a porous material different from a bulk material. When the first sintered body layer 6 is configured with the porous material, a surface area of the first sintered body layer 6 becomes large, and thus the liquid-phase working fluid F_{L} can be efficiently evaporated. In addition, when the first sintered body layer 6 is configured with the sintered body of the copper powder, the wettability with the working fluid F can be made excellent and the thermal conductivity can be improved.

Here, the average particle size (average primary particle size) of the first copper powder is not particularly limited, but may be in a range of 0.01 μm or more and 100 μm or less. In the description, the average particle size is a particle size at a volume-based integrated value of 50% in a particle size distribution measured by a laser diffraction/scattering particle size distribution measurement method.

The first sintered body layer 6 is preferably filled in at least one part of the grooves 8. In other words, the first sintered body layer 6 is preferably formed so as to include the side of the container 2 with respect to a virtual inner peripheral surface 3b obtained by imagining a case where the grooves 8 are not formed in the evaporating portion 3 of the container. More preferably, the first sintered body layer 6 is filled in some or all part of the grooves 8 in the longitudinal direction X. In particular, the first sintered body layer 6 is preferably formed to be in contact with groove bottoms of the grooves 8 as shown in FIG. 1B. Thus, the liquid-phase working fluid F_{L} transferred along the grooves 8 comes into contact with the first sintered body layer 6, and thus the liquid-phase working fluid F_{L} can be easily sucked up to the first sintered body layer 6, so that the evaporation of the liquid-phase working fluid F_{L} can be further promoted.

As shown in FIG. 1A, the inner peripheral surface of the first sintered body layer 6 is preferably configured to be closer to a central position M of the internal space S of the container 2 than a boundary surface position N located in the intermediate portion 5 where the second sintered body layer 7 and the inner peripheral surface 2a of the container 2 are in contact with each other. Thus, a part of the flow of the liquid-phase working fluid F_{L} flowing through the second sintered body layer 7 hits against the first sintered body layer 6, whereby it is possible to promote the flow of the liquid-phase working fluid F_{L} from the second sintered body layer 7 to the first sintered body layer 6. In the description, the inner peripheral surface is a surface facing the internal space S of the container 2. In the description, the outer peripheral surface is a surface along a wall surface on the side separated from the internal space S of the container 2.

### [Configuration of Second Sintered Body Layer]

The second sintered body layer 7 is a sintered body layer that is located to extend continuously to at least a part of the inner peripheral surface 5a of the intermediate portion 5 while being laminated on the inner peripheral surface 6a of the first sintered body layer 6, and is formed by sintering the second copper powder having a larger average particle size than the first copper powder. Since the second sintered body layer 7 is formed of a sintered body of the second copper powder having a larger average particle size than the first sintered body layer 6 described above, a large cavity is formed therein, and the cavity forms a flow path through which the liquid-phase working fluid F_{L} can flow, so that the liquid-phase working fluid F_{T}. can flow inside. In addition, the second sintered body layer 7 is also a portion where a temperature hardly increases as compared with the first sintered body layer 6. Therefore, the flow of the working fluid F inside the second sintered body layer 7 mainly includes, as shown in FIG. 2, a flow of the liquid-phase working fluid F_{L} sucked up on the inner peripheral surface 5a of the intermediate portion 5 toward the leading end of the evaporating portion 3 in the longitudinal direction X of the container and a flow of the gas-phase working fluid F_{g} generated mainly by the first sintered body layer 6 toward the internal space S.

As shown in FIG. 1A, the second sintered body layer 7 extends continuously from the inner peripheral surface 6a of the first sintered body layer 6 in the evaporating portion 3 to the inner peripheral surface 5a of the intermediate portion 5. Thereby, since the liquid-phase working fluid F_{L} sucked up to the second sintered body layer 7 on the inner peripheral surface 5a of the intermediate portion 5 is smoothly supplied to the inner peripheral surface 6a of the first sintered body layer 6, retention of the liquid-phase working fluid F_{L} can hardly occur in front and rear of the boundary between the intermediate portion 5 and the evaporating portion 3. As a result, a counterflow of the gas-phase working fluid F_{g} hardly occurs, so that turbulence in the circulation flow of the working fluid F can be prevented.

Here, the second sintered body layer 7 is laminated on at least a part of the inner peripheral surface 6a of the first sintered body layer 6, and more preferably laminated on the entire inner peripheral surface 6a. In particular, when the second sintered body layer 7 is laminated over a wide range of the inner peripheral surface 6a of the first sintered body layer 6, the liquid-phase working fluid F_{L} can be supplied over the wide range of the inner peripheral surface 6a of the first sintered body layer 6.

Further, the second sintered body layer 7 extends so as to be in contact with both the inner peripheral surface 6a of the first sintered body layer 6 and the inner peripheral surface 5a of the intermediate portion 5. At this time, the second sintered body layer 7 is laminated on the inner peripheral surface 6a of the first sintered body layer 6, and is located by continuously extending onto the inner peripheral surface 5a of the intermediate portion 5 in the container 2. In other words, the second sintered body layer 7 includes both an outer peripheral surface 7b located on the inner peripheral surface 6a of the first sintered body layer 6 and an outer peripheral surface 7b′ located on the inner peripheral surface 5a of the intermediate portion 5 in the container 2. Thereby, the liquid-phase working fluid F_{L} is transferred from the inner peripheral surface 5a of the intermediate portion 5 to the portion in contact with the first sintered body layer 6 along the second sintered body layer 7 extending in the longitudinal direction X of the container 2, and is evaporated from a wider range of the first sintered body layer 6. As a result, the liquid-phase working fluid F_{L} can be efficiently evaporated, and thus the thermal resistance of the heat pipe 1 can be reduced.

The second sintered body layer 7 is preferably configured such that a vapor flow of the gas-phase working fluid F_{g}, which has undergone the phase change by the evaporating portion 3, is substantially isolated from a liquid flow of the liquid-phase working fluid F_{L}, which has undergone the phase change by the condensing portion 4, at the position of the intermediate portion 5. Thus, since the liquid-phase working fluid F_{L} passing through the inside of the second sintered body layer 7 does not substantially come into contact with the gas-phase working fluid (g) passing through the internal space S, the counterflow of the gas-phase working fluid (g) can be made less likely to occur.

In particular, when the plurality of grooves 8 extending in the longitudinal direction X of the container 2 are formed on the inner peripheral surface 2a of the container 2, the second sintered body layer 7 is configured such that the liquid flow of the liquid-phase working fluid F_{L} flows at least into the internal cavity of the second sintered body layer 7. More preferably, the liquid flow of the liquid-phase working fluid F_{T}. is divided into a path passing through the plurality of grooves 8 and a path passing through the internal cavity of the second sintered body layer 7. Thus, since a larger amount of the liquid-phase working fluid F_{L} can flow in the vicinity of the portion in contact with the first sintered body layer 6, retention of the liquid-phase working fluid F_{T}. can be made less likely to occur in such a portion. Further, in the vicinity of the portion in contact with the first sintered body layer 6, the liquid-phase working fluid F_{L} is sucked up more strongly in a portion where the path passing through the plurality of grooves 8 and the path passing through the internal cavity of the second sintered body layer 7 are formed in parallel, so that the flow rate of the liquid-phase working fluid F_{L} in the intermediate portion 5 and the evaporating portion 3 is increased, thereby further improving the heat transfer characteristics of the heat pipe 1.

The second sintered body layer 7 is configured with the sintered body of the second copper powder which is a porous material and has a larger average particle size than the first copper powder. Thus, since the second sintered body layer 7 is formed with pores through which the liquid-phase working fluid F_{T}. can pass, the liquid-phase working fluid F_{T}. can be transferred from the inner peripheral surface 5a of the intermediate portion 5 to the inner peripheral surface 6a of the first sintered body layer 6 in the longitudinal direction X. In addition, when the second sintered body layer 7 is configured with the sintered body of the copper powder, the wettability with the working fluid F can be made excellent and the thermal conductivity can be improved. Therefore, the second sintered body layer 7 has high thermal conductivity, exhibits dry-out resistance to the first sintered body layer 6 from which the liquid-phase working fluid F_{T}. evaporates, and has inverse operability. Here, the inverse operability refers to performance of exhibiting a function as the heat pipe 1 even when the position of the evaporating portion 3 is higher than the position of the condensing portion 4.

Here, the average particle size (average primary particle size) of the second copper powder is not particularly limited, but may be in a range of 100 μm or more and 500 μm or less. Further, the average particle size (average primary particle size) of the second copper powder is preferably larger than the groove width of the grooves 8 from the viewpoint of not obstructing the flow path of the liquid-phase working fluid F_{L} formed in the groove 8.

The second sintered body layer 7 preferably does not fill the groove 8 from the viewpoint of not obstructing the flow path of the liquid-phase working fluid F_{T}. formed in the groove 8. Here, examples of means for forming the second sintered body layer 7 so as not to fill the groove 8 may include means for using the copper powder as the second copper powder having a larger average particle size than the first copper power described above and means for sintering the second copper powder by weakening a force applied to the copper powder when the second copper powder is loaded into the container 2.

One or both of the first sintered body layer 6 and the second sintered body layer 7 may be an annular sintered body layer having a central axis in longitudinal direction X of the container 2 (for example, having a central axis line at the central position M of the internal space S of the container 2) as shown in FIGS. 1B and 1C, but is not limited thereto.

### [Operation Principle of Heat Pipe]

Next, an operation principle of the heat pipe 1 will be described using the heat pipe 1 of the first embodiment shown in FIGS. 1 and 2. Here, the heat pipe 1 is in a state in which the liquid-phase working fluid F_{T}. is sealed in the internal space S before operation.

First, the liquid-phase working fluid F_{L} is supplied to the portion of the inner peripheral surface 5a of the intermediate portion 5 in contact with the second sintered body layer 7, along the grooves 8 extending in the longitudinal direction X on the inner peripheral surface 2a of the container 2. The means for supplying the liquid-phase working fluid F_{L} to the portion of the intermediate portion 5 in contact with the second sintered body layer 7 is not particularly limited. For example, since the liquid-phase working fluid F_{T}. can be supplied regardless of a positional relation between the intermediate portion 5 and the condensing portion 4 by using the capillary force generated when the grooves 8 come into contact with the liquid-phase working fluid F_{L}, it is possible to prevent the occurrence of dry-out.

At least one part of the liquid-phase working fluid F_{L}, which is supplied to the portion of the inner peripheral surface 5a of the intermediate portion 5 in contact with the second sintered body layer 7, are absorbed by the second sintered body layer 7 and flow into the internal cavity of the second sintered body layer 7. Here, the liquid flow of the liquid-phase working fluid F_{L} may be configured to be divided into a path passing through the plurality of grooves 8 and a path passing through the interval cavity of the second sintered body layer 7.

The liquid-phase working fluid F_{L} absorbed by the second sintered body layer 7 flows in the longitudinal direction X due to the capillary force of the second sintered body layer 7, and is absorbed by the first sintered body layer 6 in a wide range where the second sintered body layer 7 and the first sintered body layer 6 are in contact with each other. On the other hand, the working fluid F_{L} flowing through the grooves 8 without being absorbed by the second sintered body layer 7 is absorbed by the first sintered body layer 6 at a portion where the grooves 8 and the first sintered body layer 6 are close to each other.

Here, upon receiving heat from the heating element (not shown) connected thermally, the evaporating portion 3 of the heat pipe 1 evaporates the liquid-phase working fluid F_{L} on the surface of the first sintered body layer 6 to which the liquid-phase working fluid F_{L} is supplied to change the phase into the gas-phase working fluid F_{g}, and absorbs the heat as evaporation latent heat received from the heating element. In the heat pipe 1, particularly, since the liquid-phase working fluid F_{T}. can efficiently undergo the phase change into the gas-phase working fluid F_{g} over a wide range of the surface of the first sintered body layer 6, the thermal resistance of the heat pipe 1 can be significantly reduced.

The gas-phase working fluid F_{g}, which has absorbed heat in the evaporating portion 3 flows from the evaporating portion (heat receiving portion) 3 to the condensing portion (heat dissipating portion) 4 in the longitudinal direction X of the container 2 by passing through the vapor flow path that is the internal space S of the container 2, and thus the heat received from the heating element is transferred from the evaporating portion 3 to the condensing portion 4 through the intermediate portion 5. At this time, since the gas-phase working fluid (g) transferred from the evaporating portion 3 to the condensing portion 4 through the intermediate portion 5 is difficult to come into contact with the liquid-phase working fluid F_{T}. passing through the inside of the second sintered body layer 7, it is possible to prevent turbulence in the circulation flow of the working fluid F due to the counterflow of the gas-phase working fluid (g). Therefore, the heat pipe 1 can realize excellent heat transfer characteristics.

Thereafter, the gas-phase working fluid F_{g} transferred to the condensing portion 4 undergoes a phase change into a liquid phase by the heat exchange means (not shown) in the condensing portion 4. At this time, the transferred heat of the heating element is released to the outside of the heat pipe 1 as condensation latent heat. Then, the liquid-phase working fluid F_{L}, which has undergone the phase change into the liquid phase by releasing the heat in the condensing portion 4, is supplied to the portion of the inner peripheral surface 5a of the intermediate portion 5 in contact with the second sintered body layer 7, along the grooves 8 extending in the longitudinal direction X on the inner peripheral surface 2a of the container 2, and thus it is possible to form the circulation flow of the working fluid between the evaporating portion 3 and the condensing portion 4.

### Second Embodiment

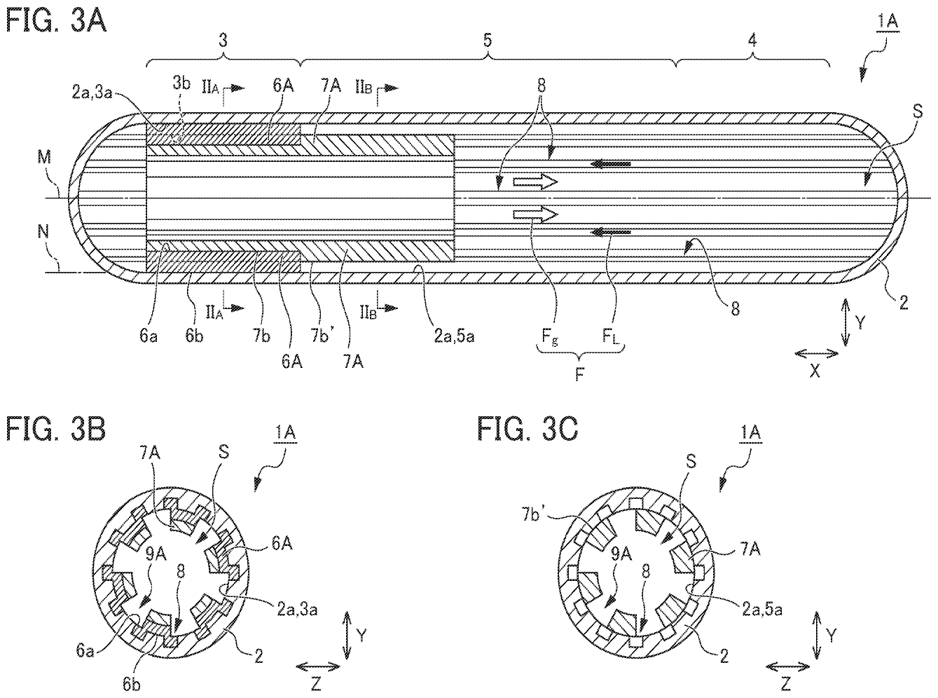

FIGS. 3A to 3C are views showing an internal structure of a heat pipe of a second embodiment, wherein FIG. 3A is a vertical cross-sectional view, FIG. 3B is a cross-sectional view taken along a line II_{A}-II_{A} in FIG. 3A, and FIG. 3C is a cross-sectional view taken along a line II_{B}-II_{B} in FIG. 3A. The same component members shown in FIGS. 3A to 3C as the component members of the heat pipe 1 shown in FIGS. 1A to 1C are denoted by the same reference numerals.

In the heat pipe 1 according to the first embodiment, both the first sintered body layer 6 and the second sintered body layer 7 are provided on the entire circumference of the inner peripheral surface 2a of the container 2, but the present invention is not limited thereto. For example, at least one of the first sintered body layer 6 and the second sintered body layer 7 may include a cutout portion in the longitudinal direction X of the container 2.

In particular, a heat pipe 1A shown in FIGS. 3A to 3C is configured such that both first sintered body layer 6A and second sintered body layer 7A include one or more cutout portions 9A in the longitudinal direction X of the container 2. Here, the cutout portion 9A is formed so as to divide both the first sintered body layer 6A and the second sintered body layer 7A into a plurality of small portions separated from each other, and a part of the first sintered body layer 6A is configured to be exposed to the internal space S. Thus, the second sintered body layer 7A can spread the liquid-phase working fluid F_{L} over a wide range of the first sintered body layer 6A, a portion is formed which is exposed to the internal space S without forming the second sintered body layer 7A on the surface of the first sintered body layer 6A, and the liquid-phase working fluid F_{L} can be directly evaporated from the surface of the first sintered body layer 6A into the internal space S at such a portion. As a result, thermal resistance of the heat pipe 1A can be further reduced.

Only one cutout portion 9A may be provided so as to cut out both the first sintered body layer 6A and the second sintered body layer 7A, but a plurality of cutout portions 9A may preferably be provided toward the inner peripheral surface 2a of the container 2 as shown in FIGS. 3A to 3C. As described above, when the plurality of cutout portions 9A are provided, the amount of the liquid-phase working fluid F_{L} directly evaporated from the surface of the first sintered body layer 6A into the internal space S increases, so that the thermal resistance of the heat pipe 1 can be made smaller.

### Third Embodiment

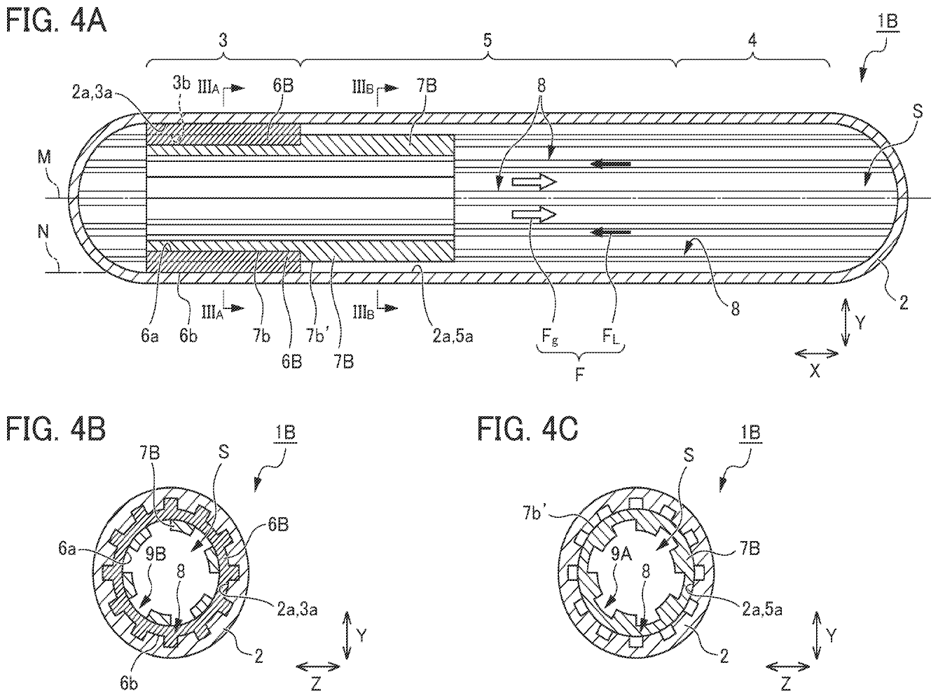

FIGS. 4A to 4C are views showing an internal structure of a heat pipe of a third embodiment, wherein FIG. 4A is a vertical cross-sectional view, FIG. 4B is a cross-sectional view taken along a line III_{A}-III_{A} in FIG. 4A, and FIG. 4C is a cross-sectional view taken along a line III_{B}-III_{B} in FIG. 4A. The same component members shown in FIGS. 4A to 4C as the component members of the heat pipe 1 shown in FIGS. 1A to 1C are denoted by the same reference numerals.

A heat pipe 1B shown in FIGS. 4A to 4C is configured such that a second sintered body layer 7B includes one or a plurality of cutout portions 9B in the longitudinal direction X of the container 2. Here, the cutout portion 9B is formed to cut out only the second sintered body layer 7B, and is configured such that a part of the first sintered body layer 6 is exposed to the internal space S. Also in the present embodiment, the second sintered body layer 7B can spread the liquid-phase working fluid F_{L} over a wide range of the first sintered body layer 6, a portion is formed which is exposed to the internal space S without forming the second sintered body layer 7B on the surface of the first sintered body layer 6, and the liquid-phase working fluid F_{L} can be directly evaporated from the surface of the first sintered body layer 6 into the internal space S at such a portion. As a result, thermal resistance of the heat pipe 1B can be further reduced.

### Fourth Embodiment

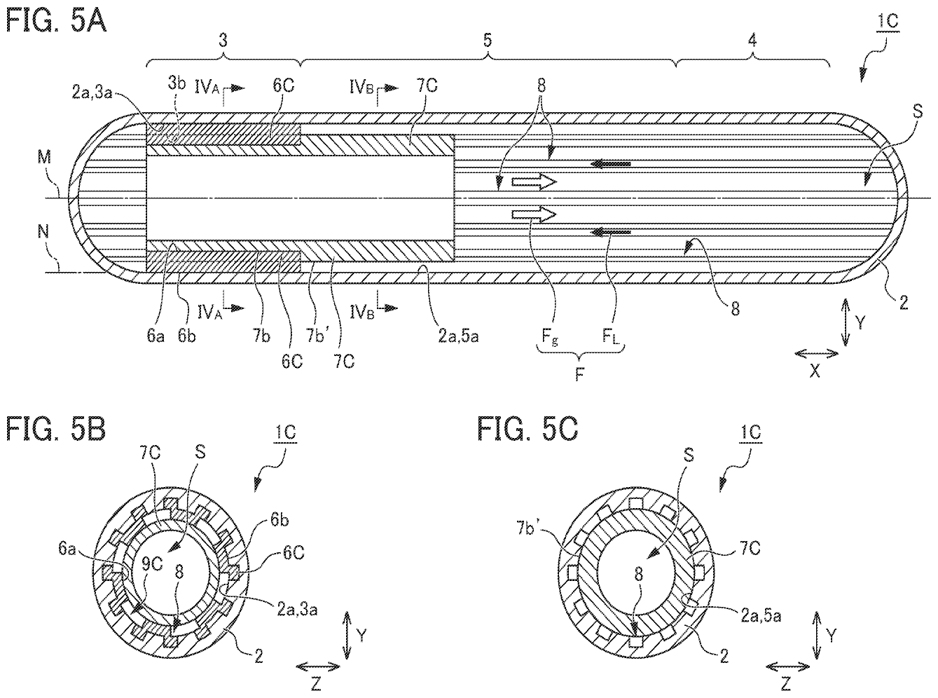

FIGS. 5A to 5C are views showing an internal structure of a heat pipe of a fourth embodiment, wherein FIG. 5A is a vertical cross-sectional view, FIG. 5B is a cross-sectional view taken along a line IV_{A}-IV_{A} in FIG. 5A, and FIG. 5C is a cross-sectional view taken along a line IV_{B}-IV_{B} in FIG. 5A. The same component members shown in FIGS. 5A to 5C as the component members of the heat pipe 1 shown in FIGS. 1A to 1C are denoted by the same reference numerals.

A heat pipe 1C shown in FIGS. 5A to 5C is configured such that a first sintered body layer 6C includes one or a plurality of cutout portions 9C in the longitudinal direction X of the container 2. Here, the cutout portion 9C is formed to cut out only the first sintered body layer 6C, and is not exposed to the internal space S. In the present embodiment, the cutout portion 9C is formed in a part of the first sintered body layer 6C, whereby a region where the first sintered body layer 6C and the second sintered body layer 7 do not contact with each other is formed, and the liquid-phase working fluid F_{L} flows through the second sintered body layer 7 in the region in the longitudinal direction X of the container without being absorbed by the first sintered body layer 6C. For this reason, even when the evaporating portion 3 is long in the longitudinal direction X, the liquid-phase working fluid F_{L} can spread over a wide range of the first sintered body layer 6C. As a result, thermal resistance of the heat pipe 1C can be further reduced.

### Fifth Embodiment

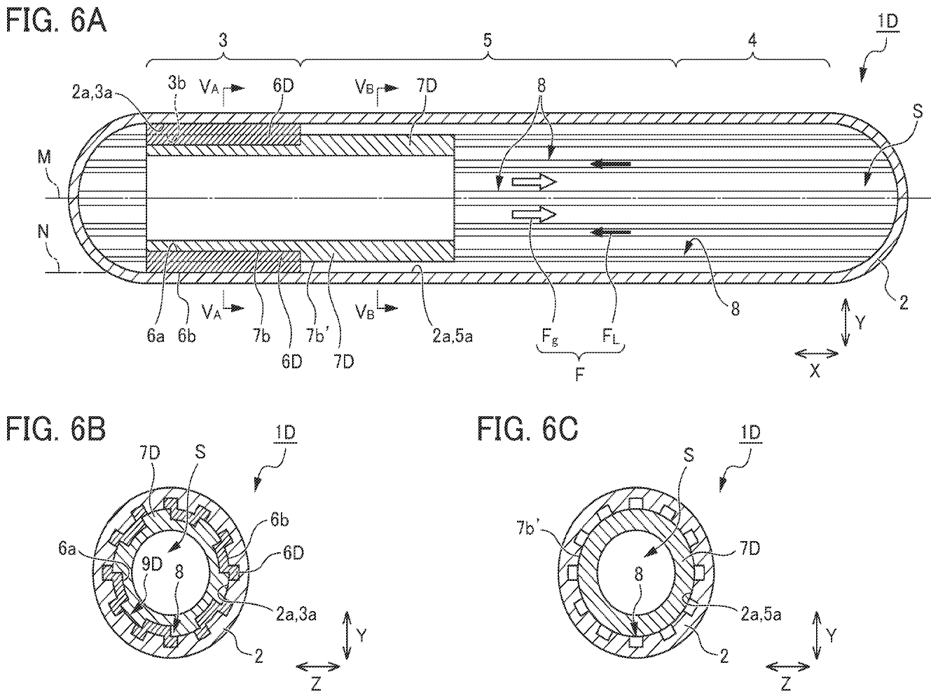

FIGS. 6A to 6C are views showing an internal structure of a heat pipe of a fifth embodiment, wherein FIG. 6A is a vertical cross-sectional view, FIG. 6B is a cross-sectional view taken along a line V_{A}-V_{A} in FIG. 6A, and FIG. 6C is a cross-sectional view taken along a line V_{B}-V_{B} in FIG. 6A. The same component members shown in FIGS. 6A to 6C as the component members of the heat pipe 1 shown in FIGS. 1A to 1C are denoted by the same reference numerals.

A heat pipe 1D shown in FIGS. 6A to 6C is configured such that a first sintered body layer 6D includes one or a plurality of cutout portions 9D in the longitudinal direction X of the container 2, and is configured such that a second sintered body layer 7D covers the cutout portions 9D of the first sintered body layer 6D. In the present embodiment, since the second sintered body layer 7D covers the cutout portions 9D of the first sintered body layer 6D, and thus a contact area between the first sintered body layer 6D and the second sintered body layer 7D can be increased, more liquid-phase working fluid F_{L} can be evaporated from the surface of the first sintered body layer 6. As a result, thermal resistance of the heat pipe 1B can be further reduced.

### Sixth Embodiment

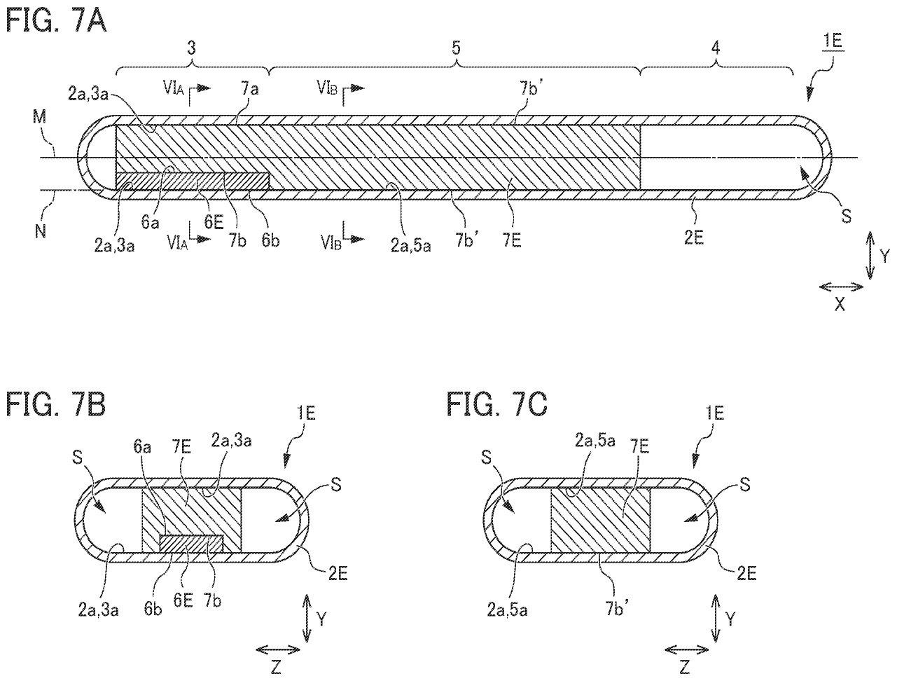

FIGS. 7A to 7C are views showing an internal structure of a heat pipe of a sixth embodiment, wherein FIG. 7A is a vertical cross-sectional view, FIG. 7B is a cross-sectional view taken along a line VI_{A}-VI_{A} in FIG. 7A, and FIG. 7C is a cross-sectional view taken along a line VI_{R}-VI_{R} in FIG. 7A.

The same component members shown in FIGS. 7A to 7C as the component members of the heat pipe 1 shown in FIGS. 1A to 1C are denoted by the same reference numerals.

In a heat pipe 1E shown in FIGS. 7A to 7C, a first sintered body layer 6E is formed on one surface of the inner peripheral surfaces 3a of the evaporating portion 3 in a container 2E as shown in FIGS. 7A and 7B. Thereby, a thickness of a portion of the heat pipe 1E in which the first sintered body layer 6E is formed can be particularly reduced, so that the thinner heat pipe 1E can be configured.

Here, a portion of a second sintered body layer 7E laminated on the first sintered body layer 6E is preferably laminated up to an inner peripheral surface 2a of the container 2E facing an inner peripheral surface 6a of the first sintered body layer 6E. In other words, the second sintered body layer 7E preferably has a portion that buries the entire container 2E in a thickness direction Y. At this time, an internal space S of the container 2E is provided on both sides in a depth direction Z of the container 2E in the longitudinal direction X of the container 2E. Thus, the second sintered body layer 7E and the internal space S are arranged in the depth direction Z of the container 2E, and are not necessary to be arranged in the thickness direction Y of the container 2E, so that the thickness of the portion where the first sintered body layer 6E is formed is made thinner.

At this time, the second sintered body layer 7E preferably is also in contact with the first sintered body layer 6E in the depth direction Z of the container 2E. Thereby, since the liquid-phase working fluid F_{T}. can be also supplied to the surface of the first sintered body layer 6E facing the depth direction Z, the liquid-phase working fluid F_{L} can be evaporated more efficiently.

### Seventh Embodiment

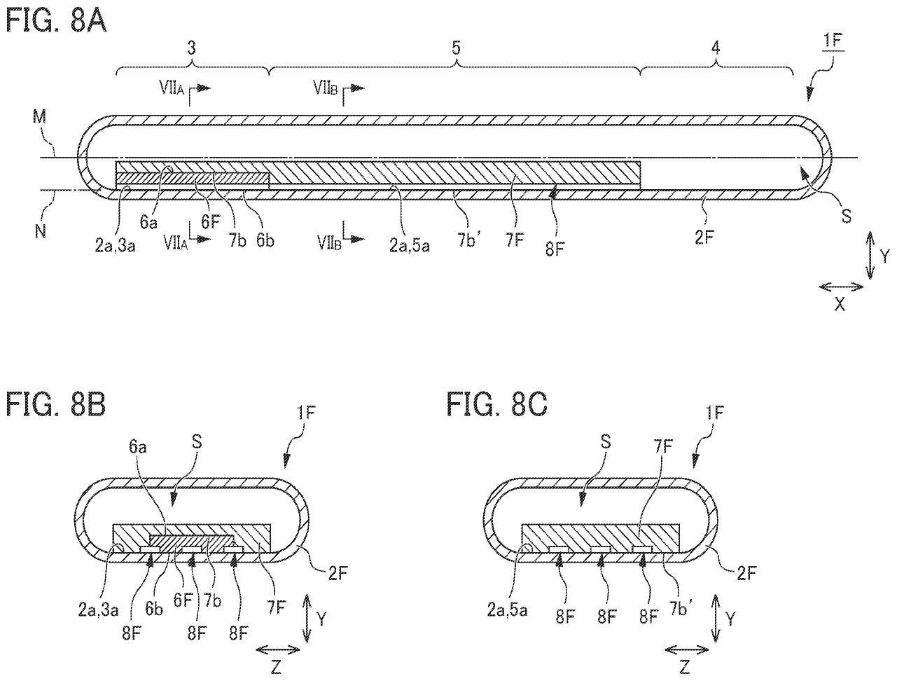

FIGS. 8A to 8C are views showing an internal structure of a heat pipe of a seventh embodiment, wherein FIG. 8A is a vertical cross-sectional view, FIG. 8B is a cross-sectional view taken along a line VII_{A}-VII_{A} in FIG. 8A, and FIG. 8C is a cross-sectional view taken along a line VII_{R}-VII_{R} in FIG. 8A. The same component members shown in FIGS. 8A to 8C as the component members of the heat pipe 1 shown in FIGS. 1A to 1C are denoted by the same reference numerals.

In a heat pipe 1F shown in FIGS. 8A to 8C, a plurality of grooves 8F extending in the longitudinal direction X of a container 2F are formed along one surface of inner peripheral surfaces 2a of the container 2E as shown in FIGS. 8A to 8C. More preferably, the grooves 8F are formed from the inner peripheral surface 2a toward a first sintered body layer 6E and a second sintered body layer 7E along the inner peripheral surface 2a of the container 2E. Thereby, since the thickness of the container 2E at the portion where the grooves 8F are formed can be made thin, the thinner heat pipe 1E can be configured.

Here, at least one part of the grooves 8F are formed in the first sintered body layer 6E in the evaporating portion 3. For example, as shown in FIG. 8B, some or all part of the grooves 8F may be formed at a boundary portion between the first sintered body layer 6E and the second sintered body layer 7E, and at this time, a part of the inner surface of the groove 8F is configured by the first sintered body layer 6E.

### Eighth Embodiment

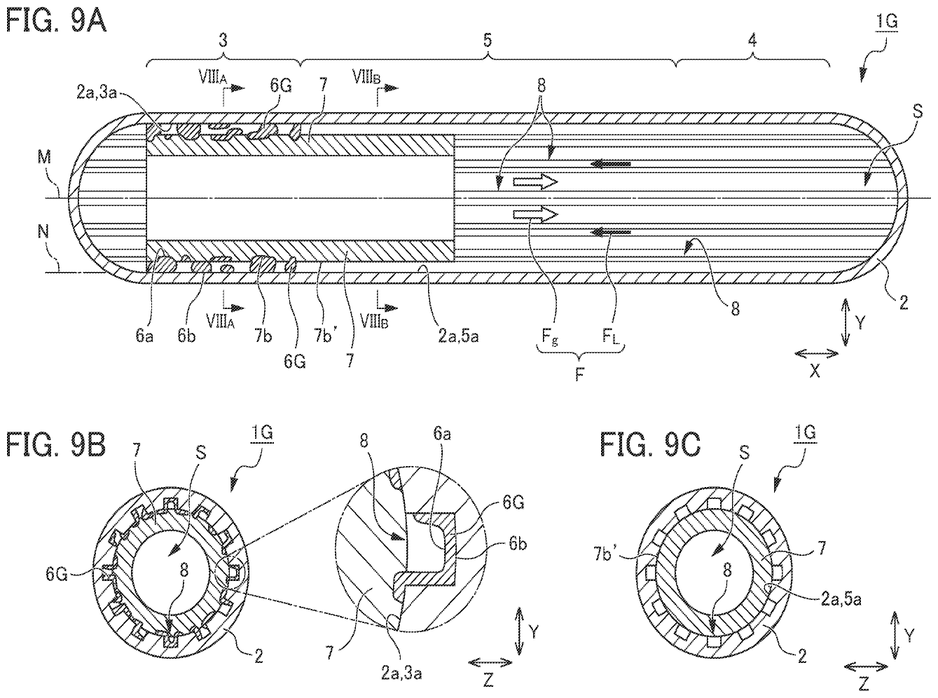

FIGS. 9A to 9C are views showing an internal structure of a heat pipe of an eighth embodiment, wherein FIG. 9A is a vertical cross-sectional view, FIG. 9B is a cross-sectional view taken along a line VIII_{A}-VIII_{A} in FIG. 9A, and FIG. 9C is a cross-sectional view taken along a line VIII_{B}-VIII_{B} in FIG. 9A. The same component members shown in FIGS. 9A to 9C as the component members of the heat pipe 1 shown in FIGS. 1A to 1C are denoted by the same reference numerals.

A heat pipe 1G is configured such that a first sintered body layer 6G is partially filled in a groove 8 in at least one of the longitudinal direction X, the thickness direction Y, and the depth direction Z of a container 2. In the heat pipe 1G shown in FIGS. 9A and 9B, particularly, the first sintered body layer 6G is configured to be filled in each part of the longitudinal direction X, the thickness direction Y, and the depth direction Z of the container 2. In addition, the first sintered body layer 6G is preferably partially formed even in a portion of the inner peripheral surface 3a of the evaporating portion 3 in the container 2 in which the groove 8 is not formed. Thus, since a surface area of the first sintered body layer 6G becomes large, the liquid-phase working fluid F_{L} can be efficiently evaporated.

An example of means for partially forming the first sintered body layer 6G inside the groove 8 or on the inner peripheral surface 3a of the evaporating portion 3 in the container 2 may include a method of aggregating a copper powder at the time of sintering by making the particle size of the first copper powder finer or adjusting the shape of the first copper powder to form a cavity in the first sintered body layer 6G which is a sintered body.

### Ninth Embodiment

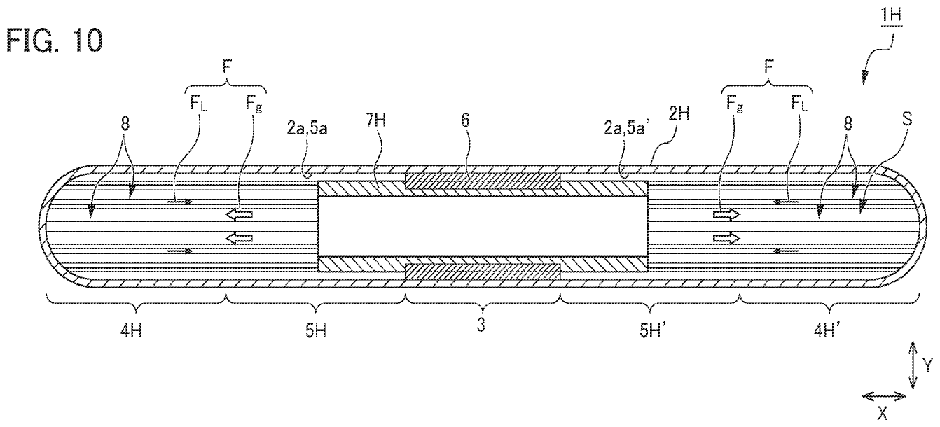

FIG. 10 is a vertical cross-sectional view showing an internal structure of a heat pipe of a ninth embodiment. The same component members shown in FIG. 10 as the component members of the heat pipe 1 shown in FIGS. 1A to 1C are denoted by the same reference numerals.

A heat pipe 1H shown in FIG. 10 includes a container 2H including an internal space S in which a working fluid F is sealed. In the container 2H, an evaporating portion 3 including a first sintered body layer 6 and a second sintered body layer 7H is provided at a central portion thereof, two condensing portions 4H and 4H′ are provided at both ends, respectively, and intermediate portions 5H and 5H′ are provided between the evaporating portion 3H and the condensing portion 4H and between the evaporating portion 3H and the condensing portion 4H′, respectively. Further, the second sintered body layer 7H is laminated on the first sintered body layer 6H, and extends continuously to an inner peripheral surface 5a of the intermediate portion 5H and to an inner peripheral surface 5a′ of the intermediate portion 5H′.

In the heat pipe 1H of the present embodiment, since the gas-phase working fluid F_{g}, which has absorbed heat in the evaporating portion 3 located at the central portion of the container 2H, is divided to flow into both the condensing portions 4H and 4H′ located on both end sides of the container 2, even when the amount of evaporation of the liquid-phase working fluid F_{L} increases using the first sintered body layer 6 and the second sintered body layer 7H together, the heat as evaporation latent heat received from the heating element can be efficiently moved to the condensing portions 4H and 4H′. Accordingly, heat transfer characteristics of the heat pipe 1H can be further improved.

### Other Embodiments

In the above-described embodiments, the cross-sectional shape of the groove 8 and the cutout portions 9A to 9D is a rectangular shape, but such a cross-sectional shape is not limited to such a configuration, and may adopt various shapes, for example, a trapezoidal shape and a substantially triangular shape.

In the above-described embodiments, the container 2 extends toward one side of the evaporating portion 3, and each of the condensing portion 4 and the intermediate portion 5 are provided at one location, but is not limited to such a configuration. For example, the container 2 may extend in a plurality of directions from the evaporating portion 3, and the condensing portion 4 and the intermediate portion 5 may be provided at a plurality of locations. In the heat pipe 1, even when the container 2 extends in a plurality of directions from the evaporating portion 3 and the flow amount of the liquid-phase working fluid F_{L} increases, the heat as evaporation latent heat received from the heating element can be efficiently moved to the plurality of condensing portions.

### <Method of Manufacturing Heat Pipe>

A specific example of a method of manufacturing the heat pipe will be described.

The shape of the container 2 such as a tubular vessel used for the heat pipe 1 can be appropriately selected from a tube material, a plate material, and foil material in accordance with the shape of the heat pipe 1. Dirt deposited onto the surface of the container 2 may lead to a decrease in heat transfer performance of the heat pipe, and thus is preferably cleaned. The cleaning can be performed by general methods, for example, solvent degreasing, electrolytic degreasing, etching, and oxidation treatment.

After a core rod (for example, a core rod made of stainless steel) having a shape serving as a mold of the first sintered body layer 6 is inserted and arranged at the internal center position of the container 2, the first copper powder as a raw material of the first sintered body layer 6 is loaded into the cavity portion formed between the inner peripheral surface 2a of the container 2 and the outer surface of the core rod, and the loaded first copper powder is sintered, thereby forming the first sintered body layer 6. The core rod is pulled out and removed from the container 2 on which the first sintered body layer 6 is formed. Here, when each of the first sintered body layers 6C and 6D includes the cutout portion 9 in the longitudinal direction X of the container 2, as in the heat pipes 1C and 1D of the fourth and fifth embodiments, the cutout portion 9 may be formed in each of the formed first sintered body layers 6C and 6D by a cutting process.

Next, a core rod (for example, a core rod made of stainless steel) having a shape serving as a mold of the second sintered body layer 7 is inserted and arranged at the internal center position of the container 2, the second copper powder as a raw material of the second sintered body layer 7 is loaded into the cavity portion formed between the inner surface of the container 2 and the outer surface of the core rod, and the loaded second copper powder is sintered, thereby forming the second sintered body layer 7. The core rod is pulled out and removed from the container 2 on which the second sintered body layer 7 is formed. Here, when each of the second sintered body layers 7A and 7B includes the cutout portion 9 in the longitudinal direction X of the container 2, as in the heat pipes 1A and 1B of the second and third embodiments, the formed second sintered body layers 7A and 7B may be formed by a cutting process.

Here, the sintering of the first and second copper powders, which are the raw materials of the first sintered body layer 6 and the second sintered body layer 7, respectively, may be performed under normal conditions and is not particularly limited. As an example of the sintering condition, heat treatment is performed under an atmosphere of a reducing gas such as hydrogen gas or a mixed gas containing hydrogen gas and inert gas (N₂, Ar, or He).

After the first sintered body layer 6 and the second sintered body layer 7 are formed in the container 2, only the other end of the container 2 is sealed while leaving a sealing port which is one end, and a working fluid F is injected from the sealing port. After the working fluid F is injected, the inside of the container 2 is brought into a pressure-reduced state by performing a deaeration process such as heating deaeration or vacuum deaeration. Thereafter, by sealing the sealing port, it is possible to manufacture the heat pipe 1.

A sealing method is not particularly limited, and may include TIG welding, resistance welding, pressure welding, and soldering, for example. A first sealing (sealing of only the other end) is a process of performing to seal the portion other than the portion where the inside gas escapes during the subsequent degassing, and a second sealing (sealing of the sealing port) is a process of performing to seal the portion where the inside gas escapes during degassing.

Although the embodiments of the present invention have been described above, the present invention can be variously modified within the scope of the present invention including all aspects included in the concept and claims of the present invention without being limited to the above embodiments.

### Examples

Hereinafter, the present invention will be described in more detail based on an example, but the present invention is not limited to the example.

### Invention Example

The heat pipe of Invention Example is the cylindrical heat pipe 1 having the internal structure shown in FIGS. 1A to 1C. As the container 2, a cylindrical container was used in which a length is 400 mm and a diameter (inner diameter) is 8 mm. The groove 8 was formed which extends over the entire length of the container 2 on the inner peripheral surface 2a of the container 2, has a rectangular shape in cross section when viewed in a cross section, and has a size by which the capillary force acts on the liquid-phase working fluid F_{L}, thereby forming the groove tube.

After a core rod made of stainless steel having a shape serving as a mold of the first sintered body layer 6 is inserted and arranged at the internal center position of the container 2 (groove tube), a copper powder (first copper powder) as a raw material of the first sintered body layer 6 having an average particle size (average primary particle size) of 100 μm was loaded into the cavity portion formed between the inner surface of the groove tube and the outer surface of the core rod. Then, heat treatment was performed on the container 2 loaded with the first copper powder under an atmosphere of a reducing gas, the copper powder was sintered, and then the core rod was pulled out and removed from the container 2. Thereby, the first sintered body layer 6 made of a copper sintered body having a length of 60 mm and an inner diameter of 6 mm was formed on one end side (evaporating portion 3) inside the container 2.

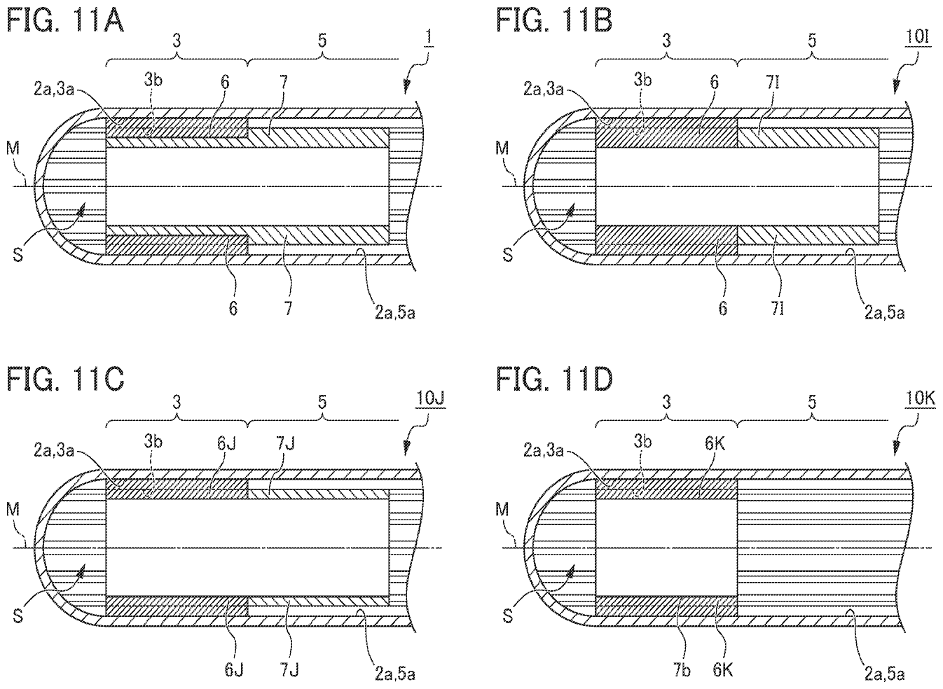

Next, a core rod made of stainless steel having a shape serving as a mold of the second sintered body layer 7 is inserted and arranged at the internal center position of the container 2 (groove tube), a copper powder (second copper powder) as a raw material of the second sintered body layer 7 having an average particle size (average primary particle size) of 200 μm was loaded into the cavity portion formed between the inner surface of the groove tube and the outer surface of the core rod. Then, heat treatment was performed on the container 2 loaded with the second copper powder under an atmosphere of a reducing gas, the copper powder was sintered, and then the core rod was pulled out and removed from the container 2. Thereby, as shown in FIG. 11A, the second sintered body layer 7 made of a copper sintered body having a length of 250 mm and an inner diameter of 4 mm was formed from one end side (evaporating portion 3) inside the container 2 to the intermediate portion 5 so as to cover the first sintered body layer 6 described above.

After the first sintered body layer 6 and the second sintered body layer 7 were formed, only the other end of the container 2 was sealed while leaving a sealing port which is one end, and water as the liquid-phase working fluid F_{L} was injected from the sealing port. Next, the inside of the container 2 was brought into a pressure-reduced state by performing a deaeration process, and then the sealing port was sealed to prepare the heat pipe 1.

### Comparative Example 1

In a heat pipe 10I of Comparative Example 1, as shown in FIG. 11B, a first sintered body layer 6 made of a copper sintered body having a length of 60 mm and an inner diameter of 4 mm was formed, and then a second sintered body layer 7I made of a copper sintered body having a length of 190 mm and an inner diameter of 4 mm was formed so as to be adjacent to the first sintered body layer 6. Others were prepared so as to have the same configuration as the heat pipe of Invention Example.

### Comparative Example 2

In a heat pipe 10J of Comparative Example 2, as shown in FIG. 11C, a first sintered body layer 6J made of a copper sintered body having a length of 60 mm and an inner diameter of 6 mm was formed, and then a second sintered body layer 7J made of a copper sintered body having a length of 190 mm and an inner diameter of 6 mm was formed so as to be adjacent to the first sintered body layer 6J. Others were prepared so as to have the same configuration as the heat pipe of Invention Example.

### Comparative Example 3

In a heat pipe 10K of Comparative Example 3, as shown in FIG. 11D, a first sintered body layer 6K made of a copper sintered body having a length of 60 mm and an inner diameter of 6 mm was formed, while a second sintered body layer 7 was not formed. Others were prepared so as to have the same configuration as the heat pipe of Invention Example.

Here, FIGS. 11A to 11D are vertical cross-sectional views showing internal structures of the heat pipes of Invention Example and Comparative Examples, wherein FIG. 11A is a partial cross-sectional view of the heat pipe 1 of Invention Example, FIG. 11B is a partial cross-sectional view of the heat pipe 10I of Comparative Example 1, FIG. 11C is a partial cross-sectional view of the heat pipe 10J of Comparative Example 2, and FIG. 11D is a partial cross-sectional view of the heat pipe 10K of Comparative Example 3.

### (Performance Evaluation)

Performance of the heat pipe was evaluated under the following conditions.
1. A heating element (heating value of 50 W to 250 W) was attached to the outer surface of the evaporating portion (heat receiving portion) which is one end side of the heat pipe.
2. Heat exchange means was attached to the condensing portion (heat dissipating portion) which is the other end side of the heat pipe.
3. A heat insulating material was attached to the intermediate portion between the evaporating portion and the condensing portion to form a heat insulating portion.
4. In a state of being installed in a horizontal direction, the quantity of heat input was measured when a difference between a temperature of the heater and a temperature of the condensing portion is minimized while heat input in the evaporating portion was gradually increased from 50 W, and the measured heat input was taken as a maximum heat transfer rate Qmax (W).
5. The difference between the temperature of the heater and the temperature of the condensing portion was measured, and a value obtained by dividing the difference by the heat input was taken as thermal resistance (° C./W).

The results of the maximum heat transfer rate Qmax were expressed as relative values when Comparative Example 3 having no second sintered body layer 7 was used as a reference (exponential ratio of 100). The results are indicated in a “Relative value of maximum heat transfer rate” column in Table 1.

Further, the results of the thermal resistance are expressed as relative values when Comparative Example 3 having no second sintered body layer 7 is used as a reference (exponential ratio of 100). The results are indicated in a “Relative value of thermal resistance” column in Table 1.

| | Container (Tubular vessel) | | | | | |
|---|---|---|---|---|---|---|
| | | | First sintered body layer | | | Second sintered body layer |
| | | | Average | | | Average |
| | | | particle | | | particle |
| | | | size of | | | size of |
| | | | first copper | Inner | | second copper |
| | Diameter | | powder | diameter | | powder |
| | (inner | | constituting | of | Length of | constituting |
| | diameter) | | first | first | first | second |
| | of | Length of | sintered | sintered | sintered | sintered |
| | container | container | body layer | body layer | body layer | body layer |
| | [mm] | [mm] | [μm] | [mm] | [mm] | [μm] |
| Invention | 8 | 400 | 100 | 6 | 60 | 200 |
| Example | | | | | | |
| Comparative | 8 | 400 | 100 | 4 | 60 | 200 |
| Example 1 | | | | | | |
| Comparative | 8 | 400 | 100 | 6 | 60 | 200 |
| Example 2 | | | | | | |
| Comparative | 8 | 400 | 100 | 6 | 60 | — |
| Example 3 | | | | | | |

| | Container (Tubular vessel) | | | Result and evaluation of | |
|---|---|---|---|---|---|
| | Second sintered body layer | | | maximum heat transfer rate | |
| | Inner | | | and thermal resistance | |
| | diameter | | | Relative | |
| | of | Length of | | value of | |
| | second | second | | maximum | Relative |
| | sintered | sintered | Configuration | heat | value of |
| | body layer | body layer | diagram of | transfer | thermal |
| | [mm] | [mm] | heat pipe | rate | resistance |
| Invention | 4 | 250 | FIG. 11 (a) | 225 | 86 |
| Example | | | | | |
| Comparative | 4 | 190 | FIG. 11 (5) | 175 | 132 |
| Example 1 | | | | | |
| Comparative | 6 | 190 | FIG. 11 (c) | 150 | 94 |
| Example 2 | | | | | |
| Comparative | — | — | FIG. 11 (d) | 100 | 100 |
| Example 3 | | | | | |

(Note 1)
The underlined bold letters in the “container (tubular vessel)” column in Table indicate that the evaluation result is out of the appropriate range of the present invention.
(Note 2)
The underlined bold letters in the “Result and evaluation of maximum heat transfer rate and thermal resistance” column in Table indicate that the evaluation result does not reach the appropriate level in Invention Example.

From the results, in the heat pipe 1 of Invention Example, the relative value of the maximum heat transfer rate Qmax was 225, and the relative value of the thermal resistance was 86 when Comparative Example 3 having no second sintered body layer 7 is used as a reference (exponential ratio of 100).

On the other hand, in each of the heat pipes 10I to 10K of Comparative Examples 1 to 3, the relative value of the maximum heat transfer rate Qmax was 175 or less, and the relative value of the thermal resistance was as large as 94 or more.

Therefore, the heat pipe 1 of Invention Example had a larger relative value of the maximum heat transfer rate Qmax and a smaller relative value of the thermal resistance compared with those of the heat pipes 10I to 10K of Comparative Examples 1 to 3, it was found that the heat pipe 1 has high heat transfer characteristics and low thermal resistance.

### EXPLANATION OF REFERENCE NUMERALS

1, 1A to 1H heat pipe
2, 2E, 2F, 2H container
2a inner peripheral surface of container
3 evaporating portion
3a inner peripheral surface of evaporating portion in container
3b virtual inner peripheral surface of evaporating portion in container
4, 4H, 4H′ condensing portion
5, 5H, 5H′ intermediate portion
5a, 5a′ inner peripheral surface of intermediate portion in container
6, 6A, 6C to 6G, 6J, 6K first sintered body layer
6a inner peripheral surface of first sintered body layer
6b outer peripheral surface of first sintered body layer
7, 7A, 7B, 7D to 7J second sintered body layer
7b outer peripheral surface of second sintered body layer located on inner peripheral surface of first sintered body layer
7b′ outer peripheral surface of second sintered body layer located on inner peripheral surface of intermediate portion in container
8, 8F groove
9A to 9D cutout portion
10I to 10K (Comparative Examples) heat pipe
F working fluid
F_{T}. liquid-phase working fluid
F_{g} gas-phase working fluid
M central axis position of internal space of container
N boundary surface position where second sintered body layer and inner peripheral surface of container are in contact with each other which are located in intermediate portion
S internal space
X longitudinal direction of container
Y thickness direction of container
Z depth direction of container

1. A heat pipe comprising a container having an internal space in which a working fluid is sealed,
the container including:
an evaporating portion that evaporates a liquid-phase working fluid to change the liquid-phase working fluid into a gas-phase working fluid;
a condensing portion that is disposed at a position separated from the evaporating portion and condenses the gas-phase working fluid to change the gas-phase working fluid into a liquid-phase working fluid; and
an intermediate portion located between the evaporating portion and the condensing portion,
the heat pipe including:
a first sintered body layer that is located on an inner peripheral surface of the evaporating portion of the container and comprises a product of sintering of a first copper powder; and
a second sintered body layer that is located to continuously extend to an inner peripheral surface of the intermediate portion and stacked on an inner peripheral surface of the first sintered body layer and comprises a product of sintering of a second copper powder having a larger average particle size than the first copper powder.

2. The heat pipe according to claim 1, wherein
a plurality of grooves extending in a longitudinal direction of the container are formed on an inner peripheral surface of the container, and
the second sintered body layer substantially isolates, at a position of the intermediate portion, a vapor flow of the gas-phase working fluid, which has undergone a phase change by the evaporating portion, from a liquid flow of the liquid-phase working fluid, which has undergone a phase change by the condensing portion, and the liquid flow has a path passing through the plurality of grooves and a path passing through an internal cavity of the second sintered body layer.

3. The heat pipe according to claim 2, wherein
the first sintered body layer is filled in at least one part of the grooves.

4. The heat pipe according to claim 1, wherein
the inner peripheral surface of the first sintered body layer is provided closer to a central position of the internal space of the container than a boundary surface position located in the intermediate portion where the second sintered body layer and the inner peripheral surface of the container are in contact with each other.

5. The heat pipe according to claim 1, wherein
the first sintered body layer is provided so as to include a side of the container with respect to a virtual inner peripheral surface obtained by imagining a case where the grooves are not formed in the evaporating portion of the container.

6. The heat pipe according to claim 1, wherein
the second sintered body layer extends so as to be in contact with both the inner peripheral surface of the first sintered body layer and the inner peripheral surface of the intermediate portion.

7. The heat pipe according to claim 1, wherein
a liquid flow of the liquid-phase working fluid is divided into a path passing through a plurality of grooves extending in the longitudinal direction of the container and a path passing through an internal cavity of the second sintered body layer.

8. The heat pipe according to claim 2, wherein
the inner peripheral surface of the first sintered body layer is provided closer to a central position of the internal space of the container than a boundary surface position located in the intermediate portion where the second sintered body layer and the inner peripheral surface of the container are in contact with each other.

9. The heat pipe according to claim 2, wherein
the first sintered body layer is provided so as to include a side of the container with respect to a virtual inner peripheral surface obtained by imagining a case where the grooves are not formed in the evaporating portion of the container.

10. The heat pipe according to claim 2, wherein
the second sintered body layer extends so as to be in contact with both the inner peripheral surface of the first sintered body layer and the inner peripheral surface of the intermediate portion.

11. The heat pipe according to claim 3, wherein
the inner peripheral surface of the first sintered body layer is provided closer to a central position of the internal space of the container than a boundary surface position located in the intermediate portion where the second sintered body layer and the inner peripheral surface of the container are in contact with each other.

12. The heat pipe according to claim 3, wherein
the first sintered body layer is provided so as to include a side of the container with respect to a virtual inner peripheral surface obtained by imagining a case where the grooves are not formed in the evaporating portion of the container.

13. The heat pipe according to claim 3, wherein
the second sintered body layer extends so as to be in contact with both the inner peripheral surface of the first sintered body layer and the inner peripheral surface of the intermediate portion.

14. The heat pipe according to claim 4, wherein
the first sintered body layer is provided so as to include a side of the container with respect to a virtual inner peripheral surface obtained by imagining a case where the grooves are not formed in the evaporating portion of the container.

15. The heat pipe according to claim 4, wherein
the second sintered body layer extends so as to be in contact with both the inner peripheral surface of the first sintered body layer and the inner peripheral surface of the intermediate portion.

16. The heat pipe according to claim 5, wherein
the second sintered body layer extends so as to be in contact with both the inner peripheral surface of the first sintered body layer and the inner peripheral surface of the intermediate portion.
